(19) United States
(12) Patent Application Publication
(10) Pub. No.: US 2024/0084135 A1
(43) Pub. Date: Mar. 14, 2024

(54) RESIN COMPOSITION, AND PREPREG, METAL-CLAD LAMINATE AND PRINTED CIRCUIT BOARD PREPARED USING THE SAME

(71) Applicant: TAIWAN UNION TECHNOLOGY CORPORATION, Zhubei City (TW)

(72) Inventors: Tsung-Hsien LIN, Zhubei City (TW); Shur-Fen LIU, Zhubei City (TW); Pin CHIEN, Zhubei City (TW); Kai-Cheng YANG, Zhubei City (TW)

(21) Appl. No.: 18/062,948

(22) Filed: Dec. 7, 2022

(30) Foreign Application Priority Data
Aug. 18, 2022 (TW) 111131150

(51) Int. Cl. C08L 79/08; C08L 63/00

(52) U.S. Cl. CPC C08L 79/08; C08L 63/00

(57) ABSTRACT

A resin composition and uses thereof are provided. The resin composition includes: (A) an epoxy resin; (B) a bismaleimide resin; and (C) a first flame retardant having a structure of formula (I):

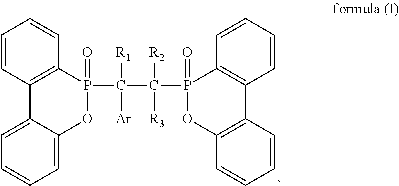

Wherein Ar is a C₃ to C₁₈ heteroaryl or a C₆ to C₁₈ aryl; R₁ is H or a C₁ to C₁₈ alkyl; and
R₂ and R₃ are independently H, a C₁ to C₁₈ alkyl, a C₃ to C₁₈ heteroaryl, or a C₆ to C₁₈ aryl.

### CLAIM FOR PRIORITY

This application claims the benefit of Taiwan Patent Application No. 111131150 filed on Aug. 18, 2022, the subject matter of which is incorporated herein in its entirety by reference.

### BACKGROUND

### Field of the Invention

The present invention provides a resin composition, especially an epoxy resin-based resin composition. The resin composition of the present invention can be used in combination with reinforcing materials to constitute a prepreg or be used as a metal foil adhesive to prepare a metal-clad laminate and a printed circuit board (PCB).

### Descriptions of the Related Art

Printed circuit boards are circuit substrates that are used for electronic devices to load other electronic components and to electrically connect components to provide a stable working circuit environment. An example of the conventional printed circuit board is a copper-clad laminate (CCL), which is primarily composed of resin(s), reinforcing material(s) and copper foil(s). Examples of resins include epoxy resins, phenolic resins, polyamine formaldehyde resins, silicone resins, and Teflon. Examples of reinforcing materials include glass fiber cloths, glass fiber mats, insulating papers, and linen cloths.

In general, a printed circuit board can be prepared by using the following method: impregnating a reinforcing material, such as a glass fiber fabric, into a resin composition (such as an epoxy resin composition), and curing the impregnated glass fiber fabric to a half-cured state (i.e., B-stage) to obtain a prepreg; superimposing certain layers of the prepregs and superimposing a metal foil on at least one external surface of the superimposed prepregs to provide a superimposed object; hot-pressing the superimposed object (i.e., C-stage) to obtain a metal-clad laminate; etching the metal foil on the surface of the metal-clad laminate to form a defined circuit pattern; and drilling a plurality of holes on the metal-clad laminate and plating these holes with a conductive material to form via holes to accomplish the preparation of the printed circuit board.

When producing a printed circuit board using an epoxy resin composition, to impart flame retardance to the prepared material, various flame retardants such as halogen-containing flame retardants and phosphorus-containing flame retardants are usually added into the composition. However, the use of halogen-containing flame retardant has been restricted due to environmental protection issues. Examples of phosphorus-containing flame retardant include phosphazene compound (such as SPB-100, available from Otsuka Chemical Co., Ltd.) or condensed phosphate esters (such as PX-200, available from Daihachi Chemical Industry Co., Ltd.). However, such flame retardants will result in low melting points, low thermal decomposition temperatures, and high ionizability at high temperatures. Also, a laminate obtained from there has a high coefficient of thermal expansion, resulting in a crack of inner layer of the laminate during the manufacturing process of a printed circuit board, lowering production yields.

WO 2010/135398 discloses a phosphorus-containing flame retardant, derivative of 9,10-dihydro-9-oxa-10-phosphaphenanthrene-10-oxide (DOPO). The derivative contains two DOPO groups at the center of the molecule and has a good thermal stability and flame retardance.

In addition, a bismaleimide (BMI) resin can be used as a substitute for epoxy resin or added into an epoxy resin composition to improve the heat resistance of the dielectric material obtained. However, the addition of a bismaleimide resin deteriorates the adhesion strength between the dielectric material and the metal foil (such as a copper foil) (i.e., peeling strength) as well as the dielectric properties. As a result, the application of a bismaleimide resin in an epoxy resin system is limited.

A resin composition capable of solving the problems mentioned earlier is needed.

### SUMMARY

The inventors found that the problems mentioned above surprisingly can be solved by using a bismaleimide resin and a flame retardant with a specific structure in an epoxy resin composition. The material obtained from the aforementioned epoxy resin composition has good glass transition temperature (Tg), coefficient of thermal expansion (z-CTE), heat resistance, dielectric properties, dielectric properties after moisture absorption, dimensional stability, adhesion with a metal layer (peeling strength), flame retardance and processibility (such as warpage performance and filling properties). In addition, the invention can mitigate the deterioration in peeling strength and dielectric properties caused by using a maleimide resin in an epoxy resin system.

Therefore, an objective of the present invention is to provide a resin composition, which comprises:
(A) an epoxy resin;
(B) a bismaleimide resin; and
(C) a first flame retardant having a structure of formula (I):

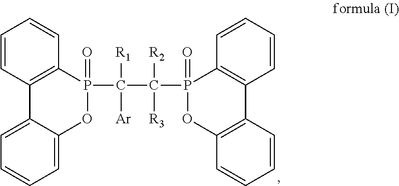

wherein
Ar is a C₃ to C₁₈ heteroaryl or a C₆ to C₁₈ aryl;
R₁ is H or a C₁ to C₁₈ alkyl; and
R₂ and R₃ are independently H, a C₁ to C₁₈ alkyl, a C₃ to C₁₈ heteroaryl, or a C₆ to C₁₈ aryl.

In some embodiments of the present invention, the weight ratio of the bismaleimide resin (B) to the first flame retardant (C) is 5:1 to 1:5.

In some embodiments of the present invention, the epoxy resin (A) is selected from the group consisting of a bisphenol epoxy resin, a phenolic epoxy resin, a diphenylethylene epoxy resin, a triazine skeleton-containing epoxy resin, a fluorene skeleton-containing epoxy resin, a triphenol methane epoxy resin, a xylylene epoxy resin, a biphenyl epoxy resin, a biphenyl aralkyl epoxy resin, a naphthalene epoxy resin, a dicyclopentadiene (DCPD) epoxy resin, an alicyclic epoxy resin, and combinations thereof.

In some embodiments of the present invention, the bismaleimide resin (B) has the structure of formula (II):

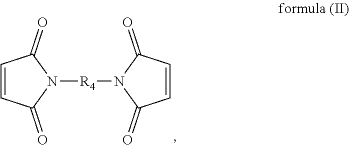

wherein R₄ is selected from the group consisting of methylene (—CH₂—), 4,4′-diphenylmethyl

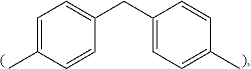

m-phenylene

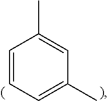

bisphenol A diphenyl ether group

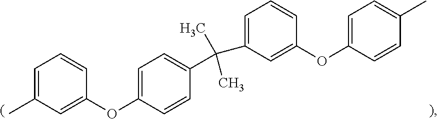

3,3′-dimethyl-5,5′-diethyl-4,4′-diphenylmethane group

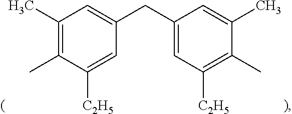

4-methyl-1,3-phenylene

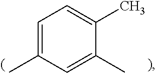

and (2,2,4-trimethyl)-1,6-hexamethylene

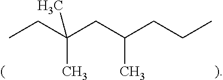

In some embodiments of the present invention, the bismaleimide resin (B) is selected from the group consisting of 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenyl ether, 3,3′-bismaleimidodiphenyl sulfone, 4,4′-bismaleimidodiphenyl sulfone, 4,4′-bismaleimidodicyclohexyl methane, 3,5-bis(4-maleimidophenyl)pyridine, 2,6-bismaleimidopyridine, 1,3-bis(maleimidomethyl)cylcohexane, 1,3-bis(maleimidomethyl)benzene, 1,1 -bis(4-maleimidopheny)cyclohexane, 1,3-bis(dichloromaleimido)benzene, 4,4′-biscitraconimidodiphenylmethane, 2,2-bis(4-maleimidophenyl)propane, 1-phenyl-1,1-bis(4-maleimidophenypethane, α,α-bis(4-maleimidophenyl)toluene, 3,5 -bismaleimido-1,2,4-triazole, N,N′-ethylenebismaleimide, N,N′-hexamethylenebismaleimide, N,N′-m-phenylenebismaleimide, N,N′-p-phenylenebismaleimide, N,N′-4,4′-diphenylmethane bismaleimide, N,N′-4,4′-diphenyl ether bismaleimide, N,N′-4,4′-diphenylsulfone bismaleimide, N,N′-4,4′-dicyclohexylmethane bismaleimide, N,N′-α,α′-4,4′-dimethylene cyclohexane bismaleimide, N,N′-m-dimethylphenylbismaleimide, N,N′-4,4′-diphenylcyclohexane bismaleimide, and combinations thereof.

In some embodiments of the present invention, the first flame retardant (C) is selected from the group consisting of

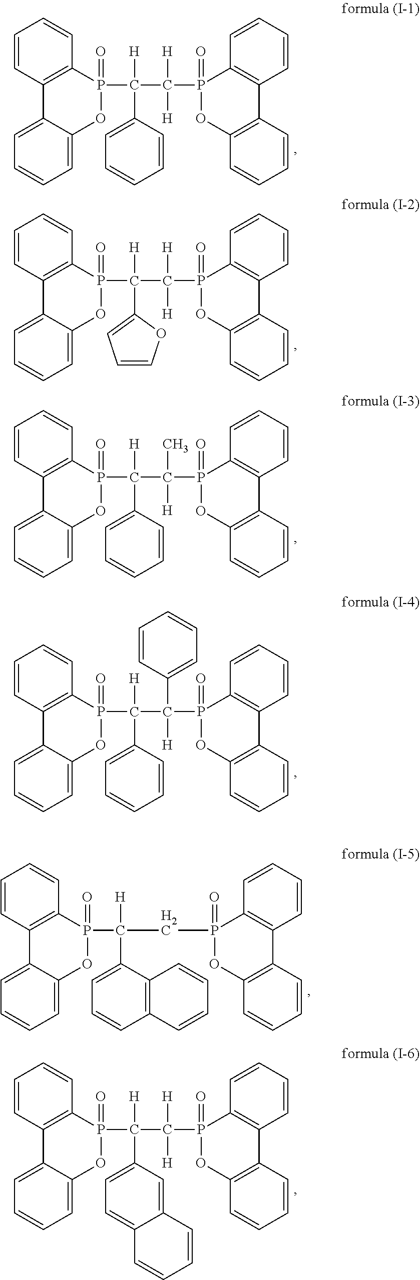

and combinations thereof.

In some embodiments of the present invention, the amounts of the bismaleimide resin (B) and the first flame retardant (C) are independently 5 wt % to 35 wt % based on the solid content of the resin composition.

In some embodiments of the present invention, the amount of the epoxy resin (A) is 3 wt % to 15 wt % based on the solid content of the resin composition.

In some embodiments of the present invention, the resin composition further comprises a curing agent selected from the group consisting of cyanate ester resin, benzoxazine resin, phenol novolac (PN) resin, styrene maleic anhydride (SMA) resin, dicyandiamide (Dicy), diaminodiphenyl sulfone (DDS), amino triazine novolac (ATN) resin, diaminodiphenylmethane, styrene-vinylphenol copolymer, and combinations thereof.

In some embodiments of the present invention, the resin composition further comprises a curing accelerator selected from the group consisting of an imidazole-based compound, a pyridine-based compound, and a combination thereof.

In some embodiments of the present invention, the resin composition further comprises a filler selected from the group consisting of silica (including hollow silica), aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene (PTFE) powders, glass beads, ceramic whiskers, carbon nanotubes, nanosized inorganic powders, and combinations thereof.

Another objective of the present invention is to provide a prepreg, prepared by impregnating a substrate with the aforementioned resin composition or by coating the aforementioned resin composition onto a substrate and drying the impregnated or coated substrate.

Another objective of the present invention is to provide a metal-clad laminate, prepared by laminating the aforementioned prepreg and a metal foil or by coating the aforementioned resin composition onto a metal foil and drying the coated metal foil.

Another objective of the present invention is to provide a printed circuit board, prepared from the aforementioned metal-clad laminate.

### BRIEF DESCRIPTION OF THE DRAWINGS

Not applicable.

### DETAILED DESCRIPTION

Hereinafter, some embodiments of the present invention will be described in detail. However, the present invention may be embodied in various embodiments and should not be limited to the embodiments described in the specification.

Unless it is additionally explained, the expressions “a,” “the,” or the like recited in the specification and the claims should include both the singular and the plural forms.

Unless it is additionally explained, while describing the components in the solution, mixture, composition or varnish in the specification and the claims, the amount of each component is calculated based on the dry weight, i.e., regardless of the weight of the solvent.

Unless it is additionally explained, the expressions “first,” “second,” or the like recited in the specification and the claims are only used to distinguish the illustrated elements or components without special meanings. Those expressions are not used to represent any priority.

Using an epoxy resin, a bismaleimide resin, and a flame retardant with a specific structure in combination, the resin composition of the present invention can provide a material having excellent glass transition temperature, coefficient of thermal expansion, heat resistance, dielectric properties, dielectric properties after moisture absorption, dimensional stability, adhesion with a metal layer (peeling strength), flame retardance and processibility (such as warpage performance and filling properties). In addition, the resin composition of the present invention can mitigate the deterioration in peeling strength and dielectric properties caused by using a maleimide resin in an epoxy resin system. The resin composition of the present application and applications thereof are described in detail below.

1. Resin Composition

The resin composition of the present invention comprises (A) an epoxy resin, (B) a bismaleimide resin, and (C) a first flame retardant having a specific structure as the essential components and may further comprise optional components. The detailed descriptions of the components are as follows.

1.1. (A) Epoxy Resin

As used herein, an epoxy resin refers to a thermosetting resin with at least two epoxy functional groups in one molecule, such as polyfunctional epoxy resins and phenolic epoxy resins. Examples of the polyfunctional epoxy resin include but are not limited to bifunctional epoxy resins, tetrafunctional epoxy resins, and octafunctional epoxy resins. The epoxy resin useful in the present invention is not particularly limited and can be selected by persons having ordinary skill in the art based on the disclosure of the present invention and depending on the needs. For example, a bromine-containing epoxy resin can impart better flame retardance properties to the thermosetting resin composition, or a halogen-free (such as bromine-free) epoxy resin can be used to meet environment-friendly requirements.

Examples of the epoxy resin include but are not limited to a bisphenol epoxy resin, a phenolic epoxy resin, a diphenylethylene epoxy resin, a triazine skeleton-containing epoxy resin, a fluorene skeleton-containing epoxy resin, a triphenol methane epoxy resin, a xylylene epoxy resin, a biphenyl epoxy resin, a biphenyl aralkyl epoxy resin, a naphthalene epoxy resin, dicyclopentadiene (DCPD) epoxy resin, and an alicyclic epoxy resin. Examples of bisphenol epoxy resin include but are not limited to bisphenol A epoxy resin, bisphenol F epoxy resin, and bisphenol S epoxy resin. Examples of the phenolic epoxy resin (such as linear phenolic epoxy resin) include but are not limited to phenol phenolic epoxy resin, methylphenol phenolic epoxy resin, bisphenol A phenolic epoxy resin, and bisphenol F phenolic epoxy resin. Examples of the epoxy resin also include diglycidyl ether compounds of polycyclic aromatic compounds such as polyfunctional phenol and anthracene.

The aforementioned epoxy resins can be used alone or in combination, depending on needs. In some embodiments of the present invention, bisphenol A epoxy resin, a phenolic epoxy resin, or a combination thereof is used.

In general, based on the solid content of the resin composition, the amount of the epoxy resin can be 3 wt % to 15 wt %. For example, based on the solid content of the resin composition, the amount of the epoxy resin can be 3 wt %, 3.5 wt %, 4 wt %, 4.5 wt %, 5 wt %, 5.5 wt %, 6 wt %, 6.5 wt %, 7 wt %, 7.5 wt %, 8 wt %, 8.5 wt %, 9 wt %, 9.5 wt %, 10 wt %, 10.5 wt %, 11 wt %, 11.5 wt %, 12 wt %, 12.5 wt %, 13 wt %, 13.5 wt %, 14 wt %, 14.5 wt %, or 15 wt %, or within a range between any two of the values described herein, but the present invention is not limited thereto.

1.2. (B) Bismaleimide Resin

As used herein, the bismaleimide resin refers to a compound or polymer with two maleimide functional groups. The bismaleimide resin has maleimide functional groups containing reactive double bond(s) and can react with other components having unsaturated functional group(s) or epoxy group(s). When the resin composition comprises bismaleimide resin, the material prepared from the resin composition can have improved heat resistance.

The bismaleimide resin can have a structure represented by the following formula (II):

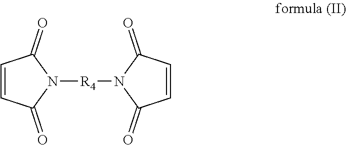

In formula (II), R₄ is selected from the group consisting of methylene (—CH₂—), 4,4′-diphenylmethyl

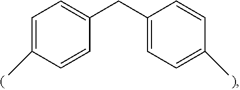

m-phenylene

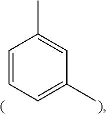

bisphenol A diphenyl ether group

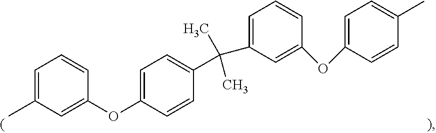

3,3′-dimethyl-5,5′-diethyl-4,4′-diphenylmethane group

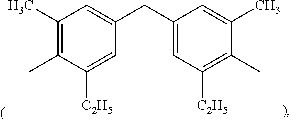

4-methyl-1,3-phenylene

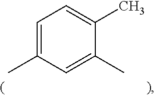

and (2,2,4-trimethyl)-1,6-hexamethylene

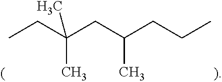

Examples of the bismaleimide resin include but are not limited to 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenyl ether, 3,3′-bismaleimidodiphenyl sulfone, 4,4′-bismaleimidodiphenyl sulfone, 4,4′-bismaleimidodicyclohexyl methane, 3,5-bis(4-maleimidophenyl)pyridine, 2,6-bismaleimidopyridine, 1,3-bis(maleimidomethyl)cylcohexane, 1,3-bis(maleimidomethyl)benzene, 1,1 -bis4-maleimidophenyl)cyclohexane, 1,3-bis(dichloromaleimido)benzene, 4,4′-biscitraconimidodiphenylmethane, 2,2-bis(4-maleimidophenyl)propane, 1-phenyl-1,1-bis(4-maleimidophenyl)ethane, α,α-bis(4-maleimidophenyl)toluene, 3,5-bismaleimido-1,2,4-triazole, N,N′-ethylenebismaleimide, N,N′-hexamethylenebismaleimide, N,N′-m-phenylenebismaleimide, N,N′-p-phenylenebismaleimide, N,N′-4,4′-diphenylmethane bismaleimide, N,N′-4,4′-diphenyl ether bismaleimide, N,N′-4,4′-diphenylsulfone bismaleimide, N,N′-4,4′-dicyclohexylmethane bismaleimide, N,N′-α,α′-4,4′-dimethylene cyclohexane bismaleimide, N,N′-m-dimethylphenylbismaleimide, N,N′-4,4′-diphenylcyclohexane bismaleimide, and N,N′-methylene bis(3-chloro-p-phenylene)bismaleimide. Commercially available bismaleimide resins include BMI-70 and BMI-80 available from KI Chemical Company, and BMI-1000, BMI-2300, BMI-4000, BMI-5000, BMI-5100, and BMI-7000 available from Daiwa Fine Chemical Company.

The aforementioned bismaleimide resins can be used alone or in combination depending on the needs of persons having ordinary skill in the art. In some embodiments of the present invention, 4,4′-diphenylmethyl bismaleimide (i.e., the embodiment of formula (II) where R₄ is 4,4′-diphenylmethyl) is used.

In general, based on the solid content of the resin composition, the amount of the bismaleimide resin can be 5 wt % to 35 wt %. For example, based on the solid content of the resin composition, the amount of the bismaleimide resin can be 5 wt %, 5.5 wt %, 6 wt %,6.5 wt %, 7 wt %, 7.5 wt %, 8 wt %, 8.5 wt %, 9 wt %, 9.5 wt %, 10 wt %, 10.5 wt %, 11 wt %, 11.5 wt %, 12 wt %, 12.5 wt %, 13 wt %, 13.5 wt %, 14 wt %, 14.5 wt %, 15 wt %, 15.5 wt %, 16 wt %, 16.5 wt %, 17 wt %, 17.5 wt %, 18 wt %, 18.5 wt %, 19 wt %, 19.5 wt %, 20 wt %, 20.5 wt %, 21 wt %, 21.5 wt %, 22 wt %, 22.5 wt %, 23 wt %, 23.5 wt %, 24 wt %, 24.5 wt %, 25 wt %, 25.5 wt %, 26 wt %, 26.5 wt %, 27 wt %, 27.5 wt %, 28 wt %, 28.5 wt %, 29 wt %, 29.5 wt %, 30 wt %, 30.5 wt %, 31 wt %, 31.5 wt %, 32 wt %, 32.5 wt %, 33 wt %, 33.5 wt %, 34 wt %, 34.5 wt %, or 35 wt %, or within a range between any two of the values described herein, but the present invention is not limited thereto.

1.3. (C) First Flame Retardant

In general, a flame retardant can improve the flame retardance of the prepared material. As used herein, the first flame retardant is a compound with a specific structure of the following formula (I):

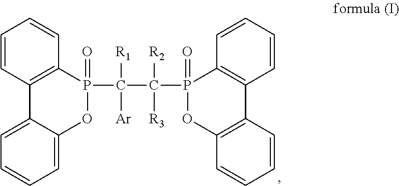

In formula (I), Ar is a C₃ to C₁₈ heteroaryl or a C₆ to C₁₈ aryl; R₁ is H or a C₁ to C₁₈ alkyl; and R₂ and R₃ are independently H, a C₁ to C₁₈ alkyl, a C₃ to C₁₈ heteroaryl, or a C₆ to C₁₈ aryl. The C₃ to C₁₈ heteroaryl refers to an aromatic cyclic or fused cyclic structure with 3 to 18 carbon atoms, which has one or more heteroatoms (such as O, N, and S) in one or more aromatic rings or fused rings. The C₆ to C₁₈ aryl refers to an aromatic monocyclic, polycyclic, or fused cyclic structure with 6 to 18 carbon atoms. Examples of the C₃ to C₁₈ heteroaryl include but are not limited to pyridyl, furyl, and imidazolyl. Examples of the C₆ to C₁₈ aryl include but are not limited to phenyl, naphthyl, and anthryl. Examples of C₁ to C₁₈ alkyl include but are not limited to methyl, ethyl, n-propyl, isopropyl, n-butyl, and isobutyl. The Ar of the first flame retardant is preferably phenyl, naphthyl, or anthryl, more preferably phenyl or naphthyl, and particularly preferably phenyl. When the first flame retardant meets the aforementioned conditions, the material prepared from the resin composition can have better properties, including better thermal expansion properties and dielectric properties after moisture absorption.

Examples of the first flame retardant (C) include

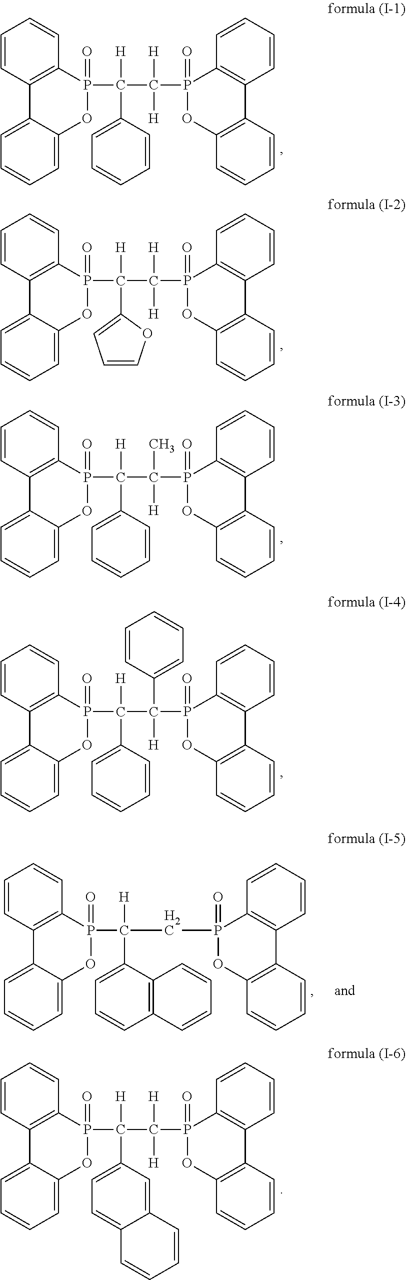

The above flame retardants can be used alone or in combination. In some embodiments of the present invention, the first flame retardant has the structure of formula (I-1).

Compared with other DOPO-based flame retardants, the first flame retardant used in the present invention comprises an aryl-substituted ethylene group as a bridging group. Without being bound by any theory, it is believed that the first flame retardant (C) has good stiffness because of the bridging group having a short chain, and the first flame retardant (C) has good chemical stability and low volatility because the aryl substituent on the ethylene group provides greater steric hindrance; therefore, the material prepared from the resin composition of the present invention can have better flame retardance.

It is found that the bismaleimide resin (B) and the first flame retardant (C) can provide a synergistic effect. Because of the synergistic effect, the resin composition of the present invention can mitigate the problem of poor adhesion between the dielectric material and the metal foil of laminate due to the addition of maleimide in an epoxy resin system and provide a laminate with good laminate properties and dielectric properties. In addition, the weight ratio of the bismaleimide resin (B) to the first flame retardant (C) is preferably 1:6 to 6:1, more preferably 1:5 to 5:1. For example, the weight ratio of the bismaleimide resin (B) to the first flame retardant (C) can be 1:6, 1:5, 1:4, 1:3, 1:2, 1:1, 2:1, 3:1, 4:1, 5:1, or 6:1, or within a range between any two of the values described herein. When the weight ratio of the bismaleimide resin (B) to the first flame retardant (C) is within the aforementioned range, the material prepared from the resin composition of the present invention can have better peeling strength, dielectric properties after moisture absorption, and filling properties.

In general, based on the solid content of the resin composition, the amount of the first flame retardant (C) can be 5 wt % to 35 wt %. For example, based on the solid content of the resin composition, the amount of the first flame retardant (C) can be 5 wt %, 5.5 wt %, 6 wt %, 6.5 wt %, 7 wt %, 7.5 wt %, 8 wt %, 8.5 wt %, 9 wt %, 9.5 wt %, 10 wt %, 10.5 wt %, 11 wt %, 11.5 wt %, 12 wt %, 12.5 wt %, 13 wt %, 13.5 wt %, 14 wt %, 14.5 wt %, 15 wt %, 15.5 wt %, 16 wt %, 16.5 wt %, 17 wt %, 17.5 wt %, 18 wt %, 18.5 wt %, 19 wt %, 19.5 wt %, 20 wt %, 20.5 wt %, 21 wt %, 21.5 wt %, 22 wt %, 22.5 wt %, 23 wt %, 23.5 wt %, 24 wt %, 24.5 wt %, 25 wt %, 25.5 wt %, 26 wt %, 26.5 wt %, 27 wt %, 27.5 wt %, 28 wt %, 28.5 wt %, 29 wt %, 29.5 wt %, 30 wt %, 30.5 wt %, 31 wt %, 31.5 wt %, 32 wt %, 32.5 wt %, 33 wt %, 33.5 wt %, 34 wt %, 34.5 wt %, or 35 wt %, or within a range between any two of the values described herein, but the present invention is not limited thereto.

### 1.4. Other Optional Components

In addition to the aforementioned components, the resin composition of the present invention may further comprise other optional components to improve specific physicochemical properties of the material prepared from the resin composition or to improve the processibility of the resin composition. The optional components can be any conventional additives known in the art, such as curing accelerators, curing agents, fillers, elastomers, dispersing agents, tougheners, viscosity modifiers, flame retardants other than the first flame retardant (C), plasticizers, coupling agents, etc. The additives are not a key feature of the present invention and can be carried out by persons having ordinary skill in the art based on the disclosure of the present invention and their ordinary skill. The following paragraphs illustrate the optional components by curing accelerators, curing agents, and fillers.

1.4.1. Curing Accelerator

A curing accelerator can promote the reaction of epoxy functional groups and lower the curing reaction temperature of the resin composition. The curing accelerator can be any substance that can promote the ring-opening reaction of epoxy functional groups and lower the curing reaction temperature. Examples of the curing accelerator include tertiary amines, quaternary amines, imidazole-based compounds, and pyridine-based compounds. The aforementioned curing accelerators can be used alone or in combination. In some embodiments of the present invention, an imidazole-based compound, a pyridine-based compound, or a combination thereof is used. Examples of the imidazole-based compound include but are not limited to 2-methyl-imidazole (2MI), 2-ethyl-4-methyl-imidazole (2E4MZ), and 2-phenyl-imidazole (2PI). Examples of the pyridine-based compound include but are not limited to 2,3-diaminopyridine, 2,5-diaminopyridine, 2,6-diaminopyridine, 4-dimethylaminopyridine, 2-amino-3-methylpyridine, 2-amino-4-methylpyridine, and 2-amino-3-nitropyridine. In some embodiments of the present invention, 2-phenyl-imidazole and 2-ethyl-4-methyl-imidazole are used.

In general, based on the solid content of the resin composition, the amount of the curing accelerator can be 0.01 wt % to 0.1 wt %. For example, based on the solid content of the resin composition, the amount of the curing accelerator can be 0.01 wt %, 0.02 wt %, 0.03 wt %, 0.04 wt %, 0.05 wt %, 0.06 wt %, 0.07 wt %, 0.08 wt %, 0.09 wt %, or 0.1 wt %, or within a range between any two of the values described herein, but the present invention is not limited thereto.

1.4.2. Curing Agent

A curing agent can be any curing agent suitable for an epoxy resin, such as hydroxyl-containing compounds, amino-containing compounds, anhydride compounds, and active ester compounds. Examples of the curing agent include but are not limited to cyanate ester resin, benzoxazine resin, phenol novolac (PN) resin, styrene maleic anhydride (SMA) resin, dicyandiamide (Dicy), diaminodiphenyl sulfone (DDS), amino triazine novolac (ATN) resin, diaminodiphenylmethane, and styrene-vinylphenol copolymer. The curing agents can be used alone or in combination. In some embodiments of the present invention, benzoxazine resin, styrene maleic anhydride resin, or a combination thereof is used.

In general, based on the solid content of the resin composition, the amount of the curing agent can be 5 wt % to 30 wt %. For example, based on the solid content of the resin composition, the amount of the curing agent can be 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %, or within a range between any two of the values described herein, but the present invention is not limited thereto.

1.4.3. Filler

Examples of the filler include but are not limited to organic or inorganic filler selected from the group consisting of silica (such as spherical, fused, non-fused, porous, or hollow silica), aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene (PTFE) powders, glass beads, ceramic whiskers, carbon nanotubes, nanosized inorganic powders, and combinations thereof. In some embodiments of the present invention, silica is used.

In general, based on the solid content of the resin composition, the amount of the filler can be 0 wt % to 45 wt %. For example, based on the solid content of the resin composition, the amount of the filler can be 1 wt %, 3 wt %, 5 wt %, 7 wt %, 10 wt %, 13 wt %, 15 wt %, 17 wt %, 20 wt %, 23 wt %, 25 wt %, 27 wt %, 30 wt %, 33 wt %, 35 wt %, 37 wt %, 40 wt %, 43 wt %, or 45 wt %, or within a range between any two of the values described herein, but the present invention is not limited thereto.

1.5. Preparation of Resin Composition

The resin composition of the present invention may be prepared into a varnish for subsequent processing by uniformly mixing the components of the resin composition, including the epoxy resin (A), the bismaleimide resin (B), the first flame retardant (C), and other optional components, with a stirrer, and dissolving or dispersing the resultant mixture in a solvent. The solvent can be any inert solvent that can dissolve or disperse the components of the resin composition but does not react with the components of the resin composition. Examples of the solvent that can dissolve or disperse the components of the resin composition include but are not limited to toluene, γ-butyrolactone, methyl ethyl ketone, cyclohexanone, butanone, acetone, xylene, methyl isobutyl ketone, N,N-dimethylformamide (DMF), N,N-dimethylacetamide (DMAc), and N-methylpyrolidone (NMP). Each of the solvents can be used alone or in combination. The solvent content in the resin composition is not particularly limited as long as the components of the resin composition can be evenly dissolved or dispersed therein. In some embodiments of the present invention, a mixture of methyl ethyl ketone and N,N-dimethylformamide is used.

2. Prepreg

The present invention also provides a prepreg prepared from the aforementioned resin composition. The prepreg is prepared by impregnating a substrate with the aforementioned resin composition or by coating the aforementioned resin composition onto a substrate and drying the impregnated or coated substrate. Examples of the substrate include but are not limited to papers, cloths or mats made from the materials selected from the group consisting of paper fibers, glass fibers, quartz fibers, organic polymer fibers, carbon fibers, and combinations thereof. Examples of the organic polymer fiber include but are not limited to high-modulus polypropylene (HMPP) fibers, polyamide fibers, ultra-high molecular weight polyethylene (UHMWPE), and liquid crystal polymer. The cloths made from the materials selected from the aforementioned group can be woven or non-woven. In some embodiments of the present invention, 2116 reinforced glass fabric is used as a reinforcing material, and the resin composition is heated and dried at 175° C. for 2 to 15 minutes (B-stage) to prepare a semi-cured prepreg.

3. Metal-Clad Laminate and Printed Circuit Board

The present invention also provides a metal-clad laminate, prepared by laminating the aforementioned prepreg and a metal foil, or by coating the aforementioned resin composition onto a metal foil and drying the coated metal foil. In the case of preparing a metal-clad laminate using a prepreg, the metal-clad laminate can be prepared by superimposing a plurality of the aforementioned prepregs, superimposing a metal foil (such as a copper foil) on at least one external surface of the dielectric layer composed of the superimposed prepregs to provide a superimposed object, and then performing a hot-pressing operation to the superimposed object to obtain the metal-clad laminate.

The aforementioned metal-clad laminate can form a printed circuit board by further patterning the external metal foil thereof.

4. Examples

4.1. Testing Methods

The present invention is further illustrated by the embodiments hereinafter, wherein the testing instruments and methods are as follows.

[Glass Transition Temperature (Tg) Test]

The laminate for evaluation is etched to remove the copper foils thereof at both sides, and the resulting unclad laminate is subjected to a glass transition temperature (Tg) test using a thermomechanical analyzer (TMA). The testing standard for the glass transition temperature is the IPC-TM-650.2.4.24C testing method, according to the Institute for Interconnecting and Packaging Electronic Circuits (IPC).

[Coefficient of Thermal Expansion (Z-CTE) Test]

A thermomechanical analyzer (TMA) is used to measure the coefficient of thermal expansion of the fully cured thermosetting resin composition in the Z-direction (in the thickness direction of the substrate) (Z-CTE). The testing method is as follows: preparing a sample of fully cured thermosetting resin composition sized at 5 mm×5 mm×1.5 mm; setting the conditions as follows: a starting temperature of 30° C., an end temperature of 330° C., a heating rate of 10° C./min, and a load of 0.05 Newton (N); and subjecting the sample to thermomechanical analysis under the aforementioned conditions in expansion/compression mode to measure the values of thermal expansion per 1° C. in the range of 30° C. to 330° C. and then averaging the measured values. The unit of the z-CTE is “%.”

[Peeling Strength Test]

The peeling strength refers to the adhesion of the metal foil to the hot-pressed laminated prepreg. The peeling strength is expressed by the force required for vertically peeling a copper foil (⅛ inch wide) from a laminate. The unit of the peel strength is “lbf/in.”

[Heat Resistance Test]

The heat resistance test is conducted according to IPC-TM-650 2.4.24.1 standard. The metal-clad laminate is immersed in a solder bath at 288° C., and the time at which delamination occurs is recorded.

[Dimensional Stability Test]

4 prepregs are laminated to prepare a testing sample. The dimensional stability test is conducted according to IPC-TM-650 2.4.24.5 standard using thermal mechanical analyzer (TMA), and the coefficient of thermal expansion (CTE) of the testing sample at a temperature lower than its Tg, α1, and the variation of CTE in Z-axis direction (total z-CTE) are measured. The α1 is measured within a temperature range of 50° C. to 120° C., and the unit is “ppm/° C.” The total z-CTE is measured within a temperature range of 50° C. to 260° C., and the unit thereof is “%.”

[Warpage Test]

The warpage test is conducted according to IPC-TM-6502.4.22 by etching one side of the metal-clad laminate to observe the bending of the laminate, and the bending rate is calculated.

[Filling Test]

The resin flow is tested by the following method. A 1037 glass fabric is impregnated with the resin composition to prepare a prepreg, and the prepreg is superimposed in the order of steel plate/copper foil/prepreg/holed template (pattern)/copper foil/steel plate. The superimposed object is placed into a pressing machine and hot-pressed at 210±5° C. under a surface pressure of 39 kg and a heating rate of 2.5° C./min. Afterward, the holed template (pattern) is taken out and cooled to room temperature. The ratio of the fully filled holes is calculated as follows: (the number of the fully filled holes/the total number of the holes)×100%.

[Flame Retardance Test]

The flame retardance test is performed according to UL94V (Vertical Burn), wherein a metal-clad laminate is held vertically and burned by using a Bunsen burner to evaluate its self-extinguishing and comburent properties. The ranking for the flame retardance level is V0>V1>V2.

[Test of Dielectric Constant (Dk) and Dielectric Loss Factor (Df)]

The dielectric constant (Dk) and dielectric loss factor (Df) are calculated according to the IPC-TM-650 2.5.5.13 standard under an operating frequency of 10 GHz using a split post dielectric resonator (SPDR). The resin content (RC) of the prepreg used for testing is 55%.

[Test of Dielectric Constant (Dk) after Moisture Absorption and Dielectric Loss Factor (Df) after Moisture Absorption]

A pressure cooker is used. After the sample is placed under 121° C. and 2 atm for 5 hours, the dielectric constant (Dk) after moisture absorption and dielectric loss factor (Df) after moisture absorption of the sample are measured according to the method described in [Test of dielectric constant (Dk) and dielectric loss factor (Df)].

4.2. List of Raw Materials Used in Examples and Comparative Examples

| Raw | |
|---|---|
| material | Description |
| BNE-210 | A bisphenol A epoxy resin, with a solid content 80%, |
| | available from Chang Chun Plastics Company. |
| PNE-177 | A phenolic epoxy resin, with a solid content of 75%, |
| | available from Chang Chun Plastics Company. |
| BMI-70 | A bismaleimide resin, available from KI Chemical |
| | Company. |
| BMI-2300 | A bismaleimide resin, available from Daiwa Kasei |
| | Kogyo Company. |
| LZ8290 | A curing agent, benzoxazine resin, with a slid content of |
| | 65%, available from Huntsman Company. |
| C500 | A curing agent, styrene maleic anhydride, available from |
| | Polyscope Company. |
| Compound of formula (I-1) | 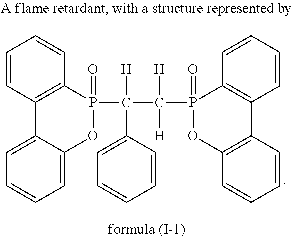 [SMILES: O=P1(CC(c2ccccc2)P2(=O)Oc3ccccc3-c3ccccc32)Oc2ccccc2-c2ccccc21] |
| Compound of formula (I-2) | 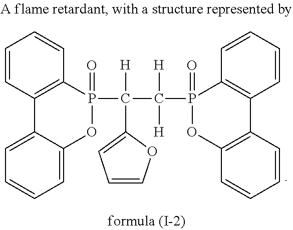 [SMILES: O=P1(CC(c2ccco2)P2(=O)Oc3ccccc3-c3ccccc32)Oc2ccccc2-c2ccccc21] |
| PX-200 | A flame retardant, available from Daihachi Chemical |
| | Industry Company. |
| SPB-100 | A flame retardant, available from Otsuka Chemical |
| | Company. |
| XZ92741 | A flame retardant, available from Blue Cube Company. |
| Compound of formula (III) | 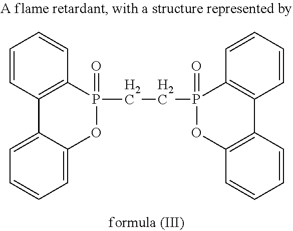 [SMILES: O=P1(CCP2(=O)Oc3ccccc3-c3ccccc32)Oc2ccccc2-c2ccccc21] |
| 2PI | A curing accelerator, available from Shikoku |
| | Chemicals Company. |
| 2E4MZ | A curing accelerator, available from Sigma-Aldrich |
| | Company. |
| 525ARI | SiO₂ filler, available from Sibelco Company. |

4.3. Preparation of Resin Composition

According to the components and proportions shown in Table 1-1, Table 1-2, and Table 2, the components were mixed with methyl ethyl ketone and N,N-dimethylformamide (both available from Methyl Company) using a stirrer at room temperature. The resultant mixture was stirred at room temperature for 60 to 120 minutes to obtain the resin compositions of Examples E1 to E19 and Comparative Examples CE1 to CE7.

TABLE 1-1

| Unit: parts by weight | | E1 | E2 | E3 | E4 | E5 | E6 | E7 | E8 | E9 | E10 |
|---|---|---|---|---|---|---|---|---|---|---|---|
| Epoxy resin (A) | BNE-210 | 13 | 13 | 13 | | 13 | 5 | 15 | 15 | 15 | 5 |
| | PNE-177 | | | | 10 | | | | | | |
| Bismaleimide | BMI-70 | 15 | | | | | | | | | |
| resin (B) | BMI-2300 | | 15 | 20 | 15 | 25 | 5 | 20 | 20 | 20 | 30 |
| Flame retardant | Compound of formula (I-1) | 17 | 17 | 17 | 15 | 5 | 25 | 15 | 15 | 15 | 15 |
| | Compound of formula (I-2) | | | | | | | | | | |
| | PX-200 | | | | | | | | | | |
| | SPB-100 | | | | | | | | | | |
| | XZ92741 | | | | | | | | | | |
| | Compound of formula (III) | | | | | | | | | | |
| Curing agent | C500 | 20 | 20 | 15 | 20 | 20 | 20 | 20 | | | |
| | LZ8290 | 5 | 5 | 5 | 10 | 7 | 5 | | 20 | 20 | 10 |
| Curing | 2PI | 0.01 | 0.01 | 0.01 | 0.05 | 0.02 | 0.01 | 0.05 | 0.05 | | |
| accelerator | 2E4MZ | | | | | | | | | 0.05 | 0.03 |
| Filler | 525ARI | 30 | 30 | 30 | 30 | 30 | 30 | 30 | 30 | 30 | 40 |

| | | | | | | | | | | |
|---|---|---|---|---|---|---|---|---|---|---|
| Weight ratio | 0.88:1 | 0.88:1 | 1.18:1 | 1:1 | 5:1 | 1:5 | 1.33:1 | 1.33:1 | 1.33:1 | 2:1 |
| (Bismaleimide resin:flame retardant) | | | | | | | | | | |

TABLE 1-2

| Unit: parts by weight | | E11 | E12 | E13 | E14 | E15 | E16 | E17 | E18 | E19 |
|---|---|---|---|---|---|---|---|---|---|---|
| Epoxy resin (A) | BNE-210 | 15 | 15 | | | | | 13 | 10 | 10 |
| | PNE-177 | | | 15 | 5 | 5 | 5 | | | |
| Bismaleimide | BMI-70 | | | | | | | 15 | | |
| resin (B) | BMI-2300 | 15 | 15 | 10 | 25 | 10 | 30 | | 30 | 5 |
| Flame retardant | Compound of formula (I-1) | 30 | 10 | 15 | 25 | 20 | 10 | | 5 | 30 |
| | Compound of formula (I-2) | | | | | | | 17 | | |
| | PX-200 | | | | | | | | | |
| | SPB-100 | | | | | | | | | |
| | XZ92741 | | | | | | | | | |
| | Compound of formula (III) | | | | | | | | | |
| Curing agent | C500 | | 15 | 10 | 10 | 15 | 15 | 20 | 14 | 14 |
| | LZ8290 | 10 | 15 | 20 | 5 | 20 | 5 | 5 | 10 | 10 |
| Curing | 2PI | | 0.05 | 0.03 | 0.01 | 0.1 | 0.08 | 0.01 | 0.1 | 0.01 |
| accelerator | 2E4MZ | 0.1 | | | | | | | | |
| Filler | 525ARI | 30 | 30 | 30 | 30 | 30 | 30 | 30 | 31 | 31 |

| | | | | | | | | | |
|---|---|---|---|---|---|---|---|---|---|
| Weight ratio | 1:2 | 1.5:1 | 1:1.5 | 1:1 | 1:2 | 3:1 | 0.88:1 | 6:1 | 1:6 |
| (Bismaleimide resin:flame retardant) | | | | | | | | | |

TABLE 2

| Unit: parts by weight | | CE1 | CE2 | CE3 | CE4 | CE5 | CE6 | CE7 |
|---|---|---|---|---|---|---|---|---|
| Epoxy resin (A) | BNE-210 | 13 | 13 | 13 | 13 | 17 | 17 | 13 |
| | PNE-177 | | | | | | | |
| Bismaleimide | BMI-70 | 15 | 15 | 15 | | 20 | | 15 |
| resin (B) | BMI-2300 | | | | 15 | | | |
| Flame retardant | Compound of formula (I-1) | | | | | | 22 | |
| | Compound of formula (I-2) | | | | | | | |
| | PX-200 | | | 17 | | | | |
| | SPB-100 | | 17 | | 17 | | | |
| | XZ92741 | 17 | | | | | | |
| | Compound of formula (III) | | | | | | | 17 |
| Curing agent | C500 | 20 | 20 | 20 | 20 | 26 | 26 | 20 |
| | LZ8290 | 5 | 5 | 5 | 5 | 7 | 5 | 5 |
| Curing | 2PI | 0.01 | 0.01 | 0.01 | 0.01 | 0.01 | 0.01 | 0.01 |
| accelerator | 2E4MZ | | | | | | | |
| Filler | 525ARI | 30 | 30 | 30 | 30 | 30 | 30 | 30 |

| | | | | | | | |
|---|---|---|---|---|---|---|---|
| Weight ratio | 1:1.13 | 1:1.13 | 1:1.13 | 1:1.13 | 0 | 0 | 1:1.13 |
| (Bismaleimide resin:flame retardant) | | | | | | | |

4.4. Preparation and Property Measurements of Laminates

Metal-clad laminates of Examples E1 to E19 and Comparative Examples CE1 to CE 7 were prepared using the prepared resin compositions, respectively. First, glass fiber cloths (Model No.: 2116; thickness: 0.08 mm) were impregnated in the resin compositions of Examples E1 to E19 and Comparative Examples CE1 to CE 7 through roll coaters, and the thicknesses of the glass fiber cloths were controlled to a proper extent. The impregnated glass fiber cloths were then placed in an oven and heated and dried at 175° C. for 2 to 15 minutes to produce semi-cured (B-stage) prepregs (the resin contents of the prepregs are 55%). Afterward, several prepregs were superimposed, and two sheets of copper foils (each 0.5 oz.) were superimposed on the respective two surfaces of the outermost layers, and then the prepared objects were placed in a hot press machine to be cured through a high-temperature hot-pressing. The hot-pressing conditions were as follows: heating to 200° C. to 220° C. at a heating rate of 3.0° C./min and hot-pressing at 200° C. to 220° C. for 180 minutes under a full pressure of 15 kg/cm² (the initial pressure was 8 kg/cm²).

The properties of the metal-clad laminates of Examples E1 to E19 and Comparative Examples CE1 to CE7, including glass transition temperature (Tg), coefficient of thermal expansion, peeling strength, heat resistance, dimensional stability, processibility (including warpage and filling properties), flame retardance, dielectric constant (Dk) and dielectric loss factor (Df), and dielectric constant (Dk) after moisture absorption and dielectric loss factor (Df) after moisture absorption, were tested according to the aforementioned testing methods. The results are tabulated in Table 3-1, Table 3-2 and Table 4.

TABLE 3-1

| | | E1 | E2 | E3 | E4 | E5 | E6 | E7 | E8 | E9 | E10 |
|---|---|---|---|---|---|---|---|---|---|---|---|
| Lami- | Tg (° C.) | 176 | 178 | 172 | 171 | 175 | 172 | 175 | 172 | 173 | 175 |
| nate | z-CTE | 2.5 | 2.5 | 2.8 | 2.7 | 2.0 | 2.5 | 2.8 | 2.8 | 2.8 | 2.8 |
| prop- | Peeling strength | 4.0 | 4.2 | 4.1 | 4.1 | 4.3 | 4.2 | 4.2 | 4.0 | 4.05 | 4.5 |
| erties | (lbf/in) | | | | | | | | | | |
| | Heat resistance | >60 | >60 | >60 | >60 | >60 | >60 | >60 | >60 | >60 | >60 |
| | (min) | | | | | | | | | | |
| | Dimensional | 250 | 200 | 300 | 300 | 200 | 240 | 300 | 300 | 320 | 330 |
| | stability | | | | | | | | | | |
| | Warpage (%) | 10 | 20 | 18 | 15 | 15 | 17 | 19 | 21 | 20 | 22 |
| | Filling properties | 95 | 86 | 86 | 87 | 88 | 90 | 92 | 90 | 89 | 85 |
| | (%) | | | | | | | | | | |
| | UL-94 level | V0 | V0 | V0 | V0 | V0 | V0 | V0 | V0 | V0 | V0 |
| Dielec- | Dk | 3.8 | 3.6 | 3.8 | 4.1 | 4.1 | 4.1 | 3.8 | 3.8 | 3.8 | 3.8 |
| tric | Dk after moisture | 3.9 | 3.7 | 3.9 | 4.2 | 4.2 | 4.2 | 3.9 | 3.9 | 3.9 | 3.9 |
| prop- | absorption | | | | | | | | | | |
| erties | Variation in Dk | 2.63 | 2.78 | 2.63 | 2.44 | 2.44 | 2.44 | 2.63 | 2.63 | 2.63 | 2.63 |
| | before and after | | | | | | | | | | |
| | moisture absorption | | | | | | | | | | |
| | (%) | | | | | | | | | | |
| | Df | 0.0077 | 0.0070 | 0.0078 | 0.0072 | 0.0069 | 0.0075 | 0.008 | 0.0088 | 0.0085 | 0.0077 |
| | Df after moisture | 0.0105 | 0.0080 | 0.010 | 0.009 | 0.008 | 0.0095 | 0.0105 | 0.0115 | 0.011 | 0.010 |
| | absorption | | | | | | | | | | |
| | Variation in Df | 36.36 | 14.29 | 28.21 | 25.00 | 15.94 | 26.67 | 31.25 | 30.68 | 29.41 | 29.87 |
| | before and after | | | | | | | | | | |
| | moisture absorption | | | | | | | | | | |
| | (%) | | | | | | | | | | |

TABLE 3-2

| | | E11 | E12 | E13 | E14 | E15 | E16 | E17 | E18 | E19 |
|---|---|---|---|---|---|---|---|---|---|---|
| Laminate | Tg (° C.) | 176 | 190 | 181 | 185 | 170 | 188 | 175 | 174 | 172 |
| properties | z-CTE | 2.7 | 2.9 | 2.6 | 2.4 | 2.7 | 2.2 | 2.5 | 2.7 | 2.7 |
| | Peeling strength (lbf/in) | 4.2 | 4.6 | 4.1 | 4.8 | 4.2 | 4.7 | 4.3 | 3.6 | 3.7 |
| | Heat resistance (min) | >60 | >60 | >60 | >60 | >60 | >60 | >60 | >60 | >60 |
| | Dimensional stability | 335 | 320 | 340 | 330 | 280 | 310 | 250 | 290 | 315 |
| | Warpage (%) | 24 | 28 | 26 | 8 | 16 | 10 | 15 | 16 | 19 |
| | Filling properties (%) | 85 | 86 | 87 | 86 | 88 | 85 | 90 | 81 | 83 |
| | UL-94 level | V0 | V0 | V0 | V0 | V0 | V0 | V0 | V0 | V0 |
| Dielectric | Dk | 3.8 | 3.9 | 3.8 | 3.7 | 3.65 | 3.6 | 3.7 | 3.6 | 3.6 |
| properties | Dk after moisture | 3.9 | 4.1 | 4.0 | 3.9 | 3.85 | 3.7 | 3.9 | 3.7 | 3.75 |
| | absorption | | | | | | | | | |
| | Variation in Dk before | 2.63 | 5.12 | 5.26 | 5.41 | 5.48 | 2.77 | 5.41 | 2.78 | 4.16 |
| | and after moisture | | | | | | | | | |
| | absorption (%) | | | | | | | | | |
| | Df | 0.0079 | 0.0090 | 0.0080 | 0.0060 | 0.0080 | 0.007 | 0.0080 | 0.007 | 0.0075 |
| | Df after moisture | 0.0105 | 0.012 | 0.0105 | 0.0077 | 0.0105 | 0.0095 | 0.011 | 0.0095 | 0.0095 |
| | absorption | | | | | | | | | |
| | Variation in Df before | 32.91 | 33.33 | 31.25 | 28.33 | 31.25 | 35.71 | 37.5 | 35.71 | 26.67 |
| | and after moisture | | | | | | | | | |
| | absorption (%) | | | | | | | | | |

TABLE 4

| | | CE1 | CE2 | CE3 | CE4 | CE5 | CE6 | CE7 |
|---|---|---|---|---|---|---|---|---|
| Laminate | Tg (° C.) | 173 | 162 | 159 | 155 | 179 | 153 | 163 |
| properties | z-CTE | 3.0 | 3.1 | 3.3 | 3.3 | 2.8 | 3.5 | 3.1 |
| | Peeling strength (lbf/in) | 3.2 | 3.1 | 2.9 | 2.6 | 2.0 | 2.8 | 2.7 |
| | Heat resistance (min) | >60 | >60 | >60 | 58 | >60 | 35 | 48 |
| | Dimensional stability | 350 | 400 | 450 | 480 | 370 | 420 | 400 |
| | Warpage (%) | 40 | 45 | 45 | 42 | 40 | 38 | 35 |
| | Filling properties (%) | 76 | 75 | 73 | 75 | 75 | 68 | 77 |
| | UL-94 level | V0 | V1 | V0 | V1 | V2 | V1 | V0 |
| Dielectric | Dk | 3.7 | 3.7 | 3.9 | 3.7 | 3.6 | 3.8 | 3.8 |
| properties | Dk after moisture absorption | 3.9 | 3.9 | 4.1 | 3.8 | 3.9 | 4.0 | 4.2 |
| | Variation in Dk before and | 5.41 | 5.41 | 5.13 | 2.7 | 8.33 | 5.26 | 10.53 |
| | after moisture absorption (%) | | | | | | | |
| | Df | 0.0080 | 0.0090 | 0.0090 | 0.0090 | 0.0085 | 0.0095 | 0.0085 |
| | Df after moisture absorption | 0.012 | 0.013 | 0.014 | 0.013 | 0.013 | 0.014 | 0.012 |
| | Variation in Df before and | 50.00 | 44.4 | 55.56 | 44.4 | 52.94 | 47.37 | 41.18 |
| | after moisture absorption (%) | | | | | | | |

As shown in Table 3-1, Table 3-2, and Table 4, the metal-clad laminates prepared by the resin compositions of the present invention have good laminate properties and dielectric properties. By contrast, Comparative Examples CE1 to CE4 and CE7 show that when the first flame retardant is replaced by a conventional flame retardant, the prepared metal-clade laminates have poor peeling strength, dimensional stability, warpage properties, and filling properties, and the variation in Dk and Df after moisture absorption is significant. Comparative Example CE5 shows that when no flame retardant is used, the metal-clad laminate has poor peeling strength and flame retardance, and the variation in Dk and Df after moisture absorption is significant. Comparative Example CE 6 shows that when the bismaleimide (B) is not used, the metal-laminate prepared has poor Tg, flame retardance, and filling properties.

The above results manifest that only when the first flame retardant (C) and the bismaleimide resin (B) are used in combination, the epoxy resin-based resin composition can provide the desired synergistic effect, that is, mitigating the problem of poor adhesion between a laminate and a metal foil due to the addition of maleimide in an epoxy resin system, and providing a laminate with good physicochemical properties and dielectric properties.

The above examples illustrate the principle and efficacy of the present invention and show the inventive features thereof. People skilled in this field may proceed with various modifications and replacements based on the disclosures and suggestions of the invention as described without departing from the principle thereof. Therefore, the scope of protection of the present invention is as defined in the claims as appended.

What is claimed is:

1. A resin composition, which comprises:
(A) an epoxy resin;
(B) a bismaleimide resin; and
(C) a first flame retardant having the structure of formula (I): 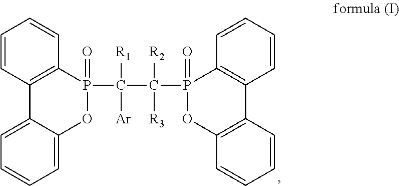
wherein
Ar is a C₃ to C₁₈ heteroaryl or a C₆ to C₁₈ aryl;
R₁ is H or a C₁ to C₁₈ alkyl; and
R₂ and R₃ are independently H, a C₁ to C₁₈ alkyl, a C₃ to C₁₈ heteroaryl, or a C₆ to C₁₈ aryl.

2. The resin composition of claim 1, wherein the weight ratio of the bismaleimide resin (B) to the first flame retardant (C) is 5:1 to 1:5.

3. The resin composition of claim 1, wherein the epoxy resin (A) is selected from the group consisting of a bisphenol epoxy resin, a phenolic epoxy resin, a diphenylethylene epoxy resin, a triazine skeleton-containing epoxy resin, a fluorene skeleton-containing epoxy resin, a triphenol methane epoxy resin, a xylylene epoxy resin, a biphenyl epoxy resin, a biphenyl aralkyl epoxy resin, a naphthalene epoxy resin, a dicyclopentadiene (DCPD) epoxy resin, an alicyclic epoxy resin, and combinations thereof.

4. The resin composition of claim 1, wherein the bismaleimide resin (B) has the structure of formula (II): 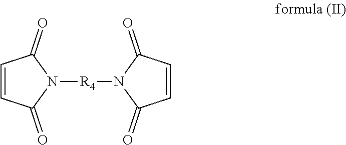
wherein R₄ is selected from the group consisting of methylene (—CH₂—), 4,4′-diphenylmethyl 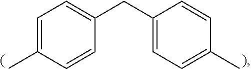
m-phenylene 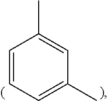
bisphenol A diphenyl ether group 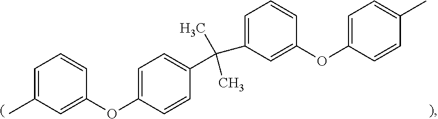
3,3′-dimethyl-5,5′-diethyl-4,4′-diphenylmethane group 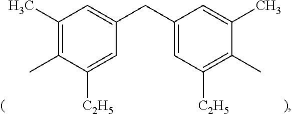
4-methyl-1,3-phenylene 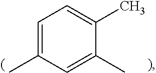
and (2,2,4-trimethyl)-1,6-hexamethylene

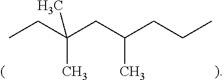

5. The resin composition of claim 1, wherein the bismaleimide resin (B) is selected from the group consisting of 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenyl ether, 3,3′-bismaleimidodiphenyl sulfone, 4,4′-bismaleimidodiphenyl sulfone, 4,4′-bismaleimidodicyclohexyl methane, 3,5-bis(4-maleimidophenyl)pyridine, 2,6-bismaleimidopyridine, 1,3-bis(maleimidomethyl)cylcohexane, 1,3-bis(maleimidomethyl)benzene, 1,1-bis(4-maleimidophenyl)cyclohexane, 1,3-bis(dichloromaleimido)benzene, 4,4′-biscitraconimidodiphenylmethane, 2,2-bis(4-maleimidophenyl)propane, 1-phenyl-1,1-bis(4-maleimidophenypethane, α,α-bis(4-maleimidophenyl)toluene, 3,5-bismaleimido-1,2,4-triazole, N,N′-ethylenebismaleimide, N,N′-hexamethylenebismaleimide, N,N′-m-phenylenebismaleimide, N,N′-p-phenylenebismaleimide, N,N′-4,4′-diphenylmethane bismaleimide, N,N′-4,4′-diphenyl ether bismaleimide, N,N′-4,4′-diphenylsulfone bismaleimide, N,N′-4,4′-dicyclohexylmethane bismaleimide, N,N′-α,α′-4,4′-dimethylene cyclohexane bismaleimide, N,N′-m-dimethylphenylbismaleimide, N,N′-4,4′-diphenylcyclohexane bismaleimide, and combinations thereof.

6. The resin composition of claim 1, wherein the first flame retardant (C) is selected from the group consisting of 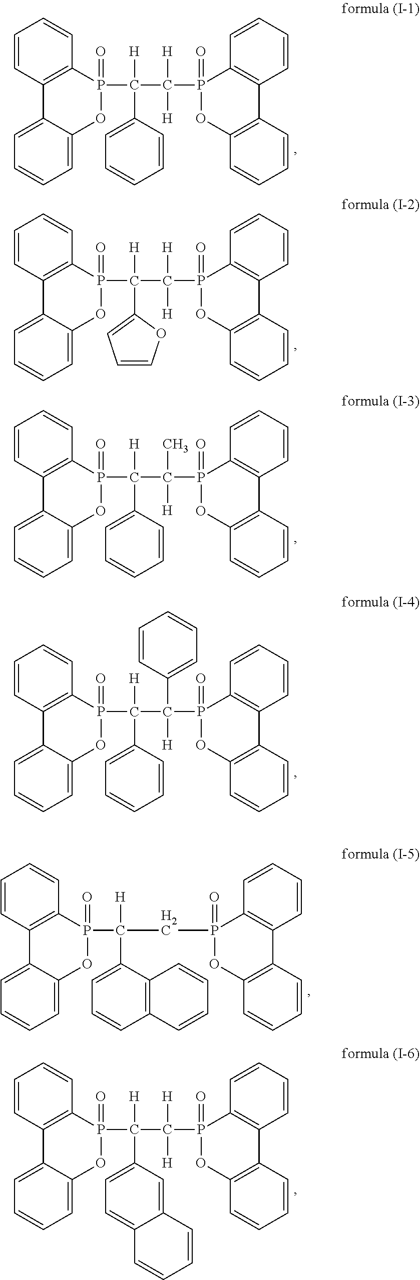
and combinations thereof.

7. The resin composition of claim 1, wherein the amounts of the bismaleimide resin (B) and the first flame retardant (C) are independently 5 wt % to 35 wt % based on the solid content of the resin composition.

8. The resin composition of claim 1, wherein the amount of the epoxy resin (A) is 3 wt % to 15 wt % based on the solid content of the resin composition.

9. The resin composition of claim 1, further comprising a curing agent selected from the group consisting of cyanate ester resin, benzoxazine resin, phenol novolac (PN) resin, styrene maleic anhydride (SMA) resin, dicyandiamide (Dicy), diaminodiphenyl sulfone (DDS), amino triazine novolac (ATN) resin, diaminodiphenylmethane, styrene-vinylphenol copolymer, and combinations thereof.

10. The resin composition of claim 1, further comprising a curing accelerator selected from the group consisting of an imidazole-based compound, a pyridine-based compound, and a combination thereof.

11. The resin composition of claim 1, further comprising a filler selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene (PTFE) powders, glass beads, ceramic whiskers, carbon nanotubes, nanosized inorganic powders, and combinations thereof.

12. A prepreg, which is prepared by impregnating a substrate with the resin composition of claim 1 or by coating the resin composition of claim 1 onto a substrate and drying the impregnated or coated substrate.

13. A metal-clad laminate, which is prepared by laminating the prepreg of claim 12 and a metal foil.

14. A printed circuit board, which is prepared from the metal-clad laminate of claim 13.

15. A metal-clad laminate, which is prepared by coating the resin composition of claim 1 onto a metal foil and drying the coated metal foil.

16. A printed circuit board, which is prepared from the metal-clad laminate of claim 15.
